(19) United States
(12) Patent Application Publication
(10) Pub. No.: US 2026/0076180 A1
(43) Pub. Date: Mar. 12, 2026

(54) SEMICONDUCTOR DEVICE AND SEMICONDUCTOR CIRCUIT

(71) Applicant: FUJI ELECTRIC CO., LTD., Kanagawa (JP)

(72) Inventors: Yoshihisa SUZUKI, Matsumoto-city (JP); Kodai YAMADA, Matsumoto-city (JP); Toshiaki SAKATA, Matsumoto-city (JP)

(21) Appl. No.: 19/308,269

(22) Filed: Aug. 24, 2025

(30) Foreign Application Priority Data
Sep. 11, 2024 (JP) 2024-157802
Dec. 11, 2024 (JP) 2024-217042

(51) Int. Cl. H01L 23/34

(52) U.S. Cl. CPC H10W 40/00

(57) ABSTRACT

There is provided a semiconductor device including: a semiconductor substrate which has an upper surface; a temperature sense diode which is arranged above the upper surface of the semiconductor substrate; an anode pad which is arranged above the upper surface of the semiconductor substrate, and which is connected to an anode of the temperature sense diode; a cathode pad which is arranged above the upper surface of the semiconductor substrate, and which is connected to a cathode of the temperature sense diode; a gate pad which is arranged above the upper surface of the semiconductor substrate; and a gate runner which is arranged above the upper surface of the semiconductor substrate, and which is connected to the gate pad, in which an entire region between the anode pad and the cathode pad does not overlap with the gate runner.

The contents of the following patent application (s) are incorporated herein by reference:

NO. 2024-157802 filed in JP on September 11, 2024

NO. 2024-217042 filed in JP on December 11, 2024.

### BACKGROUND

### TECHNICAL FIELD

The present invention relates to a semiconductor device and a semiconductor circuit.

### RELATED ART

Patent Document 1 discloses a semiconductor device including a temperature sense diode.

Patent Document 2 discloses a silicon carbide semiconductor device including a temperature monitor element for ensuring a detection current.

Patent Document 1: Japanese Patent Application Publication No. 2021-2683

Patent Document 2: Japanese Patent Application Publication No. 2013-201357

### BRIEF DESCRIPTION OF THE DRAWINGS

FIG. 1 is a top plan view showing an example of a semiconductor device 100 according to one embodiment of the present invention.

FIG. 2 is an enlarged view of a region A in FIG. 1.

FIG. 3 is an enlarged view of the region A of a semiconductor device in a comparative example.

FIG. 4 is a cross-sectional view showing an example of a line E-E' in FIG. 3.

FIG. 5 is a view showing an arrangement of electrodes in the region A.

FIG. 6 is a cross-sectional view showing an example of a line A-A' in FIG. 5.

FIG. 7 is a cross-sectional view showing an example of a line B-B' in FIG. 5.

FIG. 8 is a cross-sectional view showing an example of a line C-C' in FIG. 5.

FIG. 9 is a cross-sectional view showing an example of a line D-D' in FIG. 5.

FIG. 10 is a view showing an arrangement of electrodes in the region A of the semiconductor device according to a comparative example.

FIG. 11 is a cross-sectional view showing an example of a line A-A' in FIG. 10.

FIG. 12 is a cross-sectional view showing an example of a line B-B' in FIG. 10.

FIG. 13 is a cross-sectional view showing an example of a line C-C' in FIG. 10.

FIG. 14 is an enlarged view of the region A in FIG. 1.

FIG. 15 is a view showing an arrangement of electrodes in the region A.

FIG. 16A is a cross-sectional view showing an example of a line A-A' in FIG. 15.

FIG. 16B is a cross-sectional view showing another example of the line A-A' in FIG. 15.

FIG. 17A is a cross-sectional view showing an example of a line B-B' in FIG. 15.

FIG. 17B is a cross-sectional view showing another example of the line B-B' in FIG. 15.

FIG. 18A is a cross-sectional view showing an example of a line C-C' in FIG. 15.

FIG. 18B is a cross-sectional view showing another example of the line C-C' in FIG. 15.

FIG. 19A is a cross-sectional view showing an example of a line D-D' in FIG. 15.

FIG. 19B is a cross-sectional view showing an example of the line D-D' in FIG. 15.

FIG. 20 is a view showing a cross section C-C' of the semiconductor device 100 in a reference example.

FIG. 21 is a circuit diagram of a semiconductor circuit 500 including the semiconductor device 100 of an example.

### DESCRIPTION OF EXEMPLARY EMBODIMENTS

Hereinafter, the invention will be described through embodiments of the invention, but the following embodiments do not limit the invention according to claims. In addition, not all combinations of features described in the embodiments are essential to the solution of the invention.

As used herein, one side in a direction parallel to a depth direction of a semiconductor substrate is referred to as an "upper" side and another side is referred to as a "lower" side. One surface of two principal surfaces of a substrate, a layer or other member is referred to as an upper surface, and another surface is referred to as a lower surface. "Upper" and "lower" directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicating a height direction with respect to the ground. It should be noted that a +Z axis direction and a -Z axis direction are directions opposite to each other. When a Z axis direction is described without describing the signs, it means that the direction is parallel to the +Z axis and the -Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as the depth direction. In addition, in the present specification, a direction parallel to the upper surface and the lower surface of the semiconductor substrate may be referred to as a horizontal direction, including an X axis direction and a Y axis direction.

A region from the center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as "same" or "equal" is mentioned may include a case where an error due to a variation in manufacturing or the like is included. The error is, for example, within 10%. In addition, a case where a term such as "parallel" or "perpendicular" is mentioned may include, for example, an error within 5°.

In the present specification, a conductivity type of a doping region where doping has been carried out with an impurity is described as a p type or an n type. In the present specification, the impurity may particularly mean either a donor of the n type or an acceptor of the p type, and may be described as a dopant. In the present specification, doping means introducing the donor or the acceptor into the semiconductor substrate and turning it into a semiconductor presenting a conductivity type of the n type, or a semiconductor presenting a conductivity type of the p type.

A p+ type or an n+ type described in the present specification means a doping concentration higher than that of the p type or the n type, and a p- type or an n- type described herein means a doping concentration lower than that of the p type or the n type. In addition, in the present specification, a description of a p++ type or an n++ type means a higher doping concentration than that of the p+ type or the n+ type. In the present specification, a unit system is the SI base unit system unless otherwise noted. Although a unit of length may be indicated by cm, it may be converted to meters (m) before calculations.

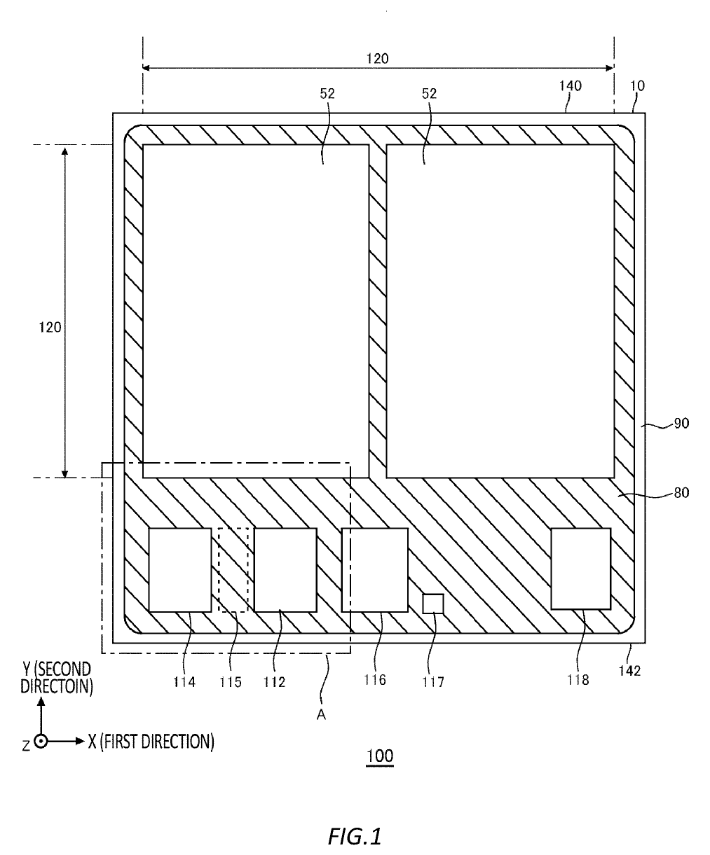

FIG. 1 is a top plan view showing an example of a semiconductor device 100 according to one embodiment of the present invention. FIG. 1 shows a position of each member projected onto an upper surface of a semiconductor substrate 10. FIG. 1 shows merely some members of the semiconductor device 100, and omits illustrations of some members.

The semiconductor device 100 includes the semiconductor substrate 10. The semiconductor substrate 10 is a substrate which is formed of a semiconductor material. As an example, the semiconductor substrate 10 is a silicon carbide semiconductor substrate, a silicon substrate, or a wide bandgap semiconductor substrate of gallium nitride or the like. In the present specification, an end portion of an outer periphery of the semiconductor substrate 10 in a top view is referred to as an outer peripheral end 140. The top view refers to a view as seen in parallel with the Z axis from an upper surface side of the semiconductor substrate 10. In addition, any end side of the outer peripheral end 140 of the semiconductor substrate 10 in the top view is referred to as a first end side 142. In the top view, a direction parallel to the first end side 142 is referred to as the X axis direction, and a direction perpendicular to the first end side 142 is referred to as the Y axis direction.

The semiconductor substrate 10 is provided with an active portion 120. The active portion 120 is a region in which a main current flows in the depth direction, between the upper surface and a lower surface of the semiconductor substrate 10 in a case where the semiconductor device 100 operates. A source electrode 52 is provided above the active portion 120. A region below the source electrode 52 may be set as the active portion 120. Alternatively, in the region below the source electrode 52, a region in which the source electrode 52 is periodically in contact with the semiconductor substrate 10 may be set as the active portion 120. Both ends of the region, in the X axis direction, in which the source electrode 52 is in contact with the semiconductor substrate 10 may be set as both ends of the active portion 120 in the X axis direction. Both ends of the region, in the Y axis direction, in which the source electrode 52 is in contact with the semiconductor substrate 10 may be set as both ends of the active portion 120 in the Y axis direction. The active portion 120 may be a rectangular region that is defined by both ends in the X axis direction and both ends in the Y axis direction.

The active portion 120 may be a region in which a semiconductor element is formed. The active portion 120 is provided with at least one of a transistor portion including a transistor element such as a MOSFET, or a diode portion including a diode element such as a free wheeling diode (FWD). In the present example, the active portion 120 is provided with the MOSFET as the transistor portion, but may be provided with another transistor element such as an IGBT.

The semiconductor device 100 may include one or more pads above the semiconductor substrate 10. The semiconductor device 100 in the present example includes an anode pad 112, a cathode pad 114, a gate pad 116, a built-in resistance measurement pad 117, and an auxiliary source pad 118. Each pad is arranged above the upper surface of the semiconductor substrate 10. It should be noted that the active portion 120 in which the semiconductor element is provided, may be provided below each pad.

The semiconductor device 100 includes a temperature sense diode 115. The temperature sense diode 115 is arranged above the upper surface of the semiconductor substrate 10. In the present example, the temperature sense diode 115 is provided outside the active portion 120. The temperature sense diode 115 is provided in a region between the anode pad 112 and the cathode pad 114. For example, when the semiconductor device 100 is small in size as the semiconductor substrate 10 is a silicon carbide semiconductor substrate, the temperature sense diode 115 may be formed between the anode pad 112 and the cathode pad 114, rather than at the center of the semiconductor substrate 10. This makes it possible for an area of the active portion 120 to be great. In the present example, the temperature sense diode 115 is a p-n junction diode.

The anode pad 112 is arranged above the upper surface of the semiconductor substrate 10, and is connected to an anode of the temperature sense diode 115. The cathode pad 114 is arranged above the upper surface of the semiconductor substrate 10, and is connected to a cathode of the temperature sense diode 115. By causing a predetermined current to flow between the anode pad 112 and the cathode pad 114, and detecting a forward voltage of the temperature sense diode 115, a temperature of the semiconductor device 100 is measured.

In the present specification, a direction in which the anode pad 112 and the cathode pad 114 are arranged is defined as a first direction. That is, the anode pad 112 and the cathode pad 114 are arranged side by side along the first direction. In addition, in the top view, a direction perpendicular to the first direction is defined as a second direction. In the present example, the first direction is the X axis direction, and the second direction is the Y axis direction. In the present example, the anode pad 112 and the cathode pad 114 face the active portion 120 in the second direction. At least a part of the anode pad 112 or the cathode pad 114 may face the active portion 120 in the second direction.

A gate voltage is applied to the gate pad 116. The gate pad 116 in the present example is connected to a gate conductive portion of the transistor portion of the active portion 120 via a gate runner described below.

The semiconductor device 100 may include a current sense portion (not shown). The current sense portion has a same structure as that of the transistor portion, and has a smaller area (corresponding to an area of a channel) than that of the transistor portion in the top view. When the semiconductor device 100 is operated, a predetermined current flows through the transistor portion, and a current in accordance with a current value of the transistor portion flows through the current sense portion.

The semiconductor device 100 includes the built-in resistance measurement pad 117. The built-in resistance measurement pad 117 is used to measure a resistance value of the built-in gate resistor (not shown) provided between the gate pad 116 and the built-in resistance measurement pad 117, before a product shipment. The built-in resistance measurement pad 117 is arranged in a vicinity of the gate pad 116 on a path of a metal runner 131 (a gate runner 130), and is directly connected to the metal runner 131. However, the semiconductor device 100 may not include the built-in resistance measurement pad 117. The semiconductor device 100 includes the auxiliary source pad 118 connected to the source electrode 52. The source electrode 52 and the auxiliary source pad 118 may be a single electrode provided continuously. The active portion 120 in which the semiconductor element is provided is provided below the auxiliary source pad 118. However, the semiconductor device 100 may not include the auxiliary source pad 118.

Each pad is formed of a metal material such as aluminum. The plurality of pads are arranged in a predetermined direction between the active portion 120 and the first end side 142 on the upper surface of the semiconductor substrate 10. It should be noted that the number and the types of pads which are provided in the semiconductor substrate 10 are not limited to the example shown in FIG. 1.

A protective film 80 made of polyimide or the like is provided above the upper surface of the semiconductor substrate 10. The protective film 80 may cover parts of the source electrode 52 and each pad. The protective film 80 is provided with openings for exposing the source electrode 52 and each pad upwards. The source electrode 52 and each pad are wire-bonded at the openings, and are connected to an external circuit. In FIG. 1, the protective film 80 is hatched.

An edge termination structure portion 90 is provided between the active portion 120 and each pad, and the outer peripheral end 140 of the semiconductor substrate 10, on the upper surface of the semiconductor substrate 10. The edge termination structure portion 90 may be arranged in an annular shape to surround the active portion 120 and each pad on the upper surface of the semiconductor substrate 10. The edge termination structure portion 90 in the present example is arranged along the outer peripheral end 140 of the semiconductor substrate 10. The edge termination structure portion 90 reduces an electric field strength of the semiconductor substrate 10 on the upper surface side. The edge termination structure portion 90 has, for example, a structure of a guard ring, a field plate, a RESURF, and a combination of them.

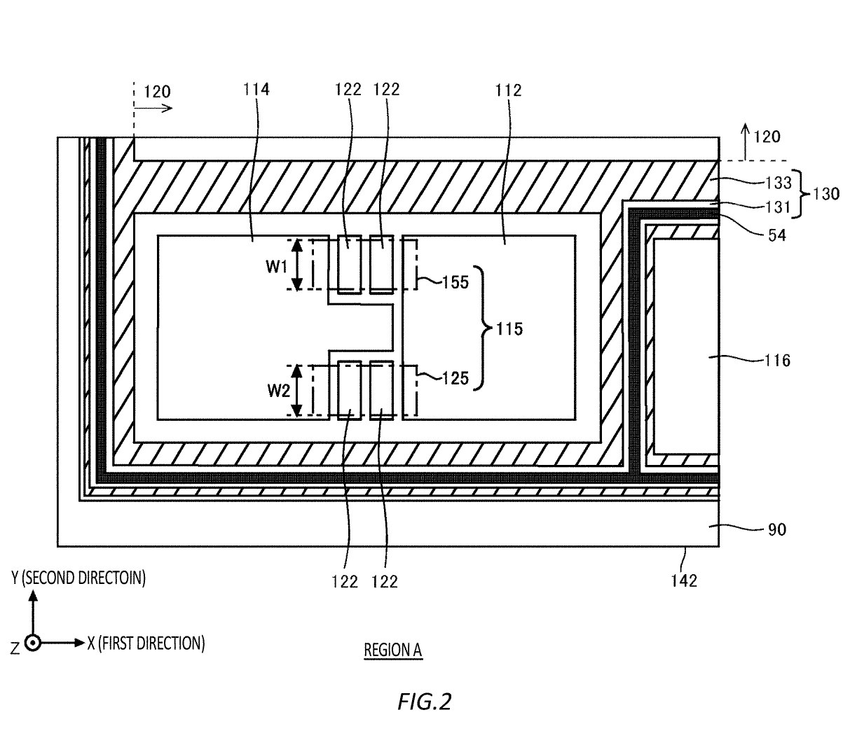

FIG. 2 is an enlarged view of a region A in FIG. 1. The region A is a region around the anode pad 112 and the cathode pad 114. Note that FIG. 2 omits illustrations of an interlayer dielectric film 38, the source electrode 52, and a metal electrode 62 described below.

The temperature sense diode 115 in the present example is provided in the region between the anode pad 112 and the cathode pad 114. The temperature sense diode 115 in the present example has a main diode 155 and a protection diode 125. An anode of the main diode 155 is connected to the anode pad 112, and a cathode of the main diode 155 is connected to the cathode pad 114. The forward voltage of the temperature sense diode 115 may be a forward voltage of the main diode 155.

The protection diode 125 has a p-n junction orientation opposite to that of the temperature sense diode 115. That is, a cathode of the protection diode 125 is connected to the anode pad 112, and an anode of the protection diode 125 is connected to the cathode pad 114. By including the protection diode 125, it is possible to protect the main diode 155 even when a reverse voltage is applied to the anode pad 112 and the cathode pad 114.

Both of the main diode 155 and the protection diode 125 may be provided between the anode pad 112 and the cathode pad 114. Note that the temperature sense diode 115 may not have the protection diode 125.

A connection metal 122 may be provided above the main diode 155. The connection metal 122 connects multiple p-n junctions of the main diode 155 in series. The connection metal 122 may also be provided above the protection diode 125.

In the second direction, a length W1 of the main diode 155 may be greater than a length W2 of the protection diode 125. This makes it possible to reduce areas of the anode pad 112, the cathode pad 114, and the temperature sense diode 115, even when the protection diode 125 is provided. The length W1 may be at least 1.5 times or more, or may be at least two times or more of the length W2.

In the second direction, the anode pad 112 or the cathode pad 114 may not be provided between the main diode 155 or the protection diode 125, and the gate runner 130. This makes it possible to ensure areas of the main diode 155 and protection diode 125, even when areas of the anode pad 112 and the cathode pad 114 are reduced, in comparison with those of a comparative example described below.

The gate runner 130 is arranged above the upper surface of the semiconductor substrate 10. The gate runner 130 is connected to the gate pad 116. The gate runner 130 is provided to surround the active portion 120 and each pad, along the edge termination structure portion 90. In addition, the gate runner 130 in the present example is provided between the anode pad 112 and the cathode pad 114, and the active portion 120. That is, the gate runner 130 in the present example surrounds the temperature sense diode 115, the anode pad 112, and the cathode pad 114, in the top view.

The gate runner 130 has a poly runner 133 and a metal runner 131. The poly runner 133 is the gate runner 130 of polysilicon, and the metal runner 131 is the gate runner 130 of metal.

The poly runner 133 is arranged to surround the anode pad 112, the cathode pad 114, and the active portion 120 from below the gate pad 116. The metal runner 131 has a part arranged along the edge termination structure portion 90 of the semiconductor substrate 10, and a part arranged to surround the gate pad 116. In the present example, between the anode pad 112 and the cathode pad 114, and the active portion 120, the metal runner 131 is not provided, and the poly runner 133 is provided. In FIG. 2, the poly runner 133 is marked with widely spaced hatching.

The metal runner 131 is formed above the poly runner 133. The interlayer dielectric film 38 is formed between the metal runner 131 and the poly runner 133. A contact hole 54 is formed in the interlayer dielectric film 38, and the metal runner 131 is connected to the poly runner 133 via the contact hole 54. In FIG. 2, the contact hole 54 is marked with dark hatching. In a direction perpendicular to an extension direction of the gate runner 130, a width of the metal runner 131 may be smaller than that of the poly runner 133.

In the present example, an entire region between the anode pad 112 and the cathode pad 114 does not overlap with the gate runner 130. The region between the anode pad 112 and the cathode pad 114 may be a region sandwiched between the anode pad 112 and the cathode pad 114, or may be a region overlapping with any straight line connecting the anode pad 112 and the cathode pad 114. This makes it possible to suppress a short circuit between the anode pad 112 and the cathode pad 114, as described below. In the present example, the entire region between the anode pad 112 and the cathode pad 114 does not overlap with the poly runner 133. In addition, the region does not overlap with the metal runner 131, either.

The connection metal 122 may be provided in the region between the anode pad 112 and the cathode pad 114. An entire region between the anode pad 112 and the connection metal 122 may also not overlap with the gate runner 130. In addition, an entire region between the cathode pad 114 and the connection metal 122 may also not overlap with the gate runner 130. In addition, an entire region between the connection metals 122 may also not overlap with the gate runner 130. An entire region of the connection metal 122 may not overlap with the poly runner 133.

The anode pad 112 and the cathode pad 114 may not overlap with the gate runner 130. In the present example, the anode pad 112 and the cathode pad 114 are surrounded by the gate runner 130, and are not connected to the gate runner 130. The connection metal 122 may also not overlap with the gate runner 130.

A distance between the anode pad 112 and the cathode pad 114 may be 50μm or less, may be 40μm or less, or may be 30μm or less. The distance may be 5 μm or more. In the present example, the distance is 15 μm or more and 20 μm or less. The distance may be a distance between the anode pad 112 and the cathode pad 114 at positions closest to the gate runner 130. The distance may also be a shortest distance between the anode pad 112 and the cathode pad 114. When the connection metal 122 is provided between the anode pad 112 and the cathode pad 114, the description regarding the distance can be applied to any of a distance between the anode pad 112 and the connection metal 122, a distance between the cathode pad 114 and the connection metal 122, and a distance between the connection metals 122.

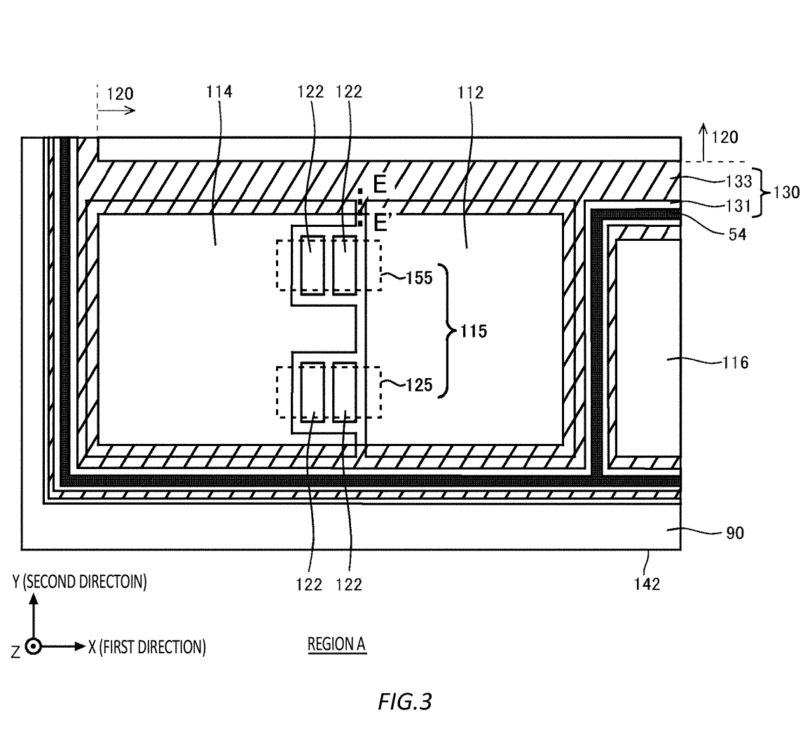

FIG. 3 is an enlarged view of the region A of a semiconductor device in a comparative example. In the semiconductor device of the comparative example, in the region between the anode pad 112 and the cathode pad 114, a vicinity of an end portion in the second direction overlaps with the gate runner 130. In addition, parts of the anode pad 112 and the cathode pad 114 also overlap with the gate runner 130. In addition, in the second direction, the cathode pad 114 is provided between the main diode 155 or the protection diode 125, and the gate runner 130; and the cathode pad 114 also overlaps with the gate runner 130. In the present example, the gate runner 130 which overlaps with the anode pad 112 or the cathode pad 114 is the poly runner 133.

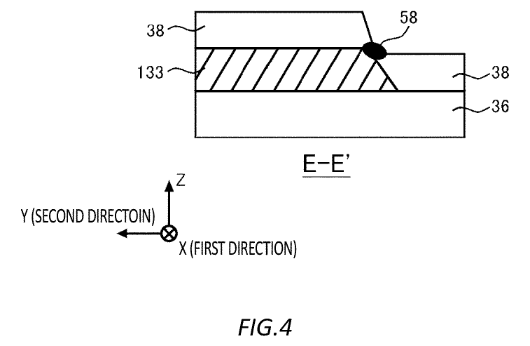

FIG. 4 is a cross-sectional view showing an example of a line E-E' in FIG. 3. FIG. 4 is a YZ cross section that crosses an end portion of the poly runner 133 in the second direction. FIG. 4 shows only a configuration above a field oxide film 36 provided above the upper surface of the semiconductor substrate 10.

The anode pad 112 and the cathode pad 114 may be formed by separating one pad through metal etching. The cross section E-E' is a cross section passing through the region between the anode pad 112 and the cathode pad 114 which are separated by the metal etching.

The gate runner 130 is provided above the field oxide film 36. In FIG. 4, the poly runner 133 is provided above the field oxide film 36. The interlayer dielectric film 38 is formed above the field oxide film 36 and the poly runner 133. In this manner, the poly runner 133 is insulated from the anode pad 112 and the cathode pad 114. The interlayer dielectric film 38 is, as an example, boron-doped silicate glass (BPSG: Boron Phosphorus Silicate Glass or BSG: Boron Silicate Glass).

When coverage of the interlayer dielectric film 38 is poor for some reason, a part of the gate runner 130 may be exposed. In particular, there may be poor coverage at a step part at an end in a direction perpendicular to the extension direction of the gate runner 130. In addition, in a case where the interlayer dielectric film 38 is PSG, the coverage is often poorer than a case of BPSG. In FIG. 4, the coverage is poor at a step part at an end of the poly runner 133 on a negative side in the second direction, and a part of the poly runner 133 is exposed.

In that state, when the pad is formed and is separated into the anode pad 112 and the cathode pad 114 by the metal etching, there may remain a residue 58 which could not be removed by the metal etching due to high adhesion between the pad and the poly runner 133. When the residue 58 remains, the anode pad 112 and the cathode pad 114 may be connected to be short-circuited. The residue 58 may be an aluminum alloy that is a material of the pad, or may be a barrier metal when the barrier metal is formed below the pad.

In the semiconductor device 100 of the example shown in FIG. 2, the entire region between the anode pad 112 and the cathode pad 114 does not overlap with the gate runner 130, and thus there is no concern that the residue 58 occurs even when the coverage of the interlayer dielectric film 38 is poor. Therefore, it is possible to prevent a short circuit of the anode pad 112 and the cathode pad 114.

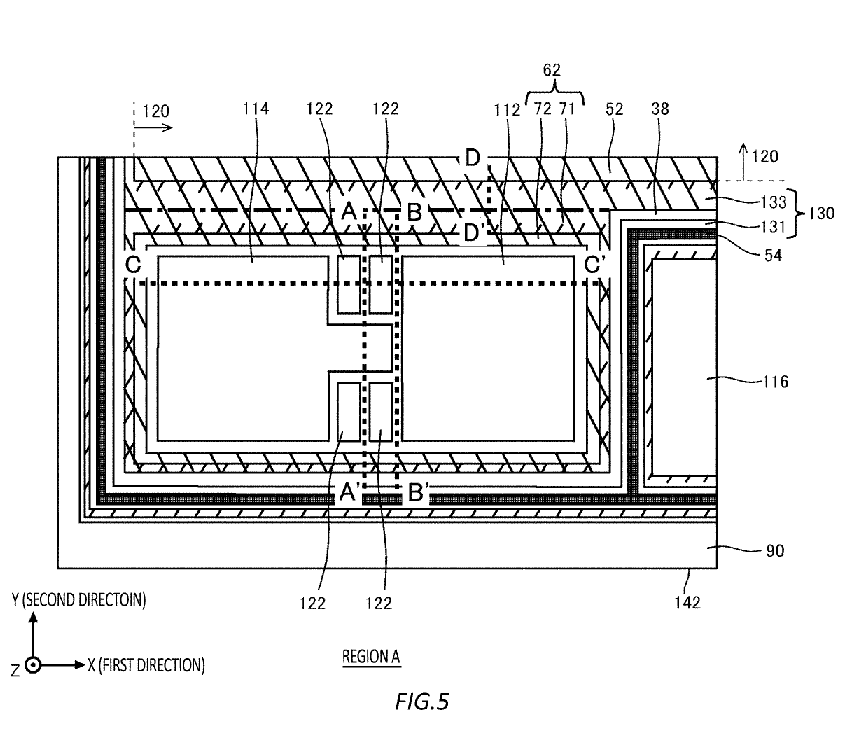

FIG. 5 is a view showing an arrangement of electrodes in the region A. In addition to FIG. 2, FIG. 5 shows an arrangement of the interlayer dielectric film 38, the source electrode 52, and the metal electrode 62. It should be noted that the arrangement of the source electrode 52 and metal electrode 62 is shown with hatching. In addition, the interlayer dielectric film 38 shows a location that is exposed in the top view. Note that in FIG. 5, the temperature sense diode 115 is omitted. In addition, the poly runner 133 is hatched only at the end portion. Note that polysilicon may also be formed below the gate pad 116. The source electrode 52 is provided from above the active portion 120 to a position overlapping with the gate runner 130 in the second direction.

The semiconductor device 100 may further include the metal electrode 62. The metal electrode 62 is arranged above the upper surface of the semiconductor substrate 10. The metal electrode 62 in the present example surrounds the anode pad 112 and the cathode pad 114. Note that the metal electrode 62 in the present example is not connected to the anode pad 112 and the cathode pad 114.

The metal electrode 62 may be an electrode of a source potential. In the present example, the metal electrode 62 is a part of the source electrode 52. In the present example, a boundary between the metal electrode 62 and the source electrode 52 is indicated by a dash- single dotted line above the gate runner 130. For the convenience of description in the present specification, the source electrode 52 and the metal electrode 62 are described separately, but both may be a single electrode provided continuously.

The metal electrode 62 in the present example has a first part 71 and a second part 72. The first part 71 is a part that overlaps with the gate runner 130. The first part 71 in the present example is a part of the metal electrode 62 which overlaps with the poly runner 133. In the gate runner 130 in the present example, a width of the poly runner 133 is greater than a width of the metal runner 131.

The second part 72 is a part that extends to an inside further than the gate runner 130. The second part 72 in the present example is a part that is positioned on an inside further than the poly runner 133. In the present specification, the "inside" may refer to a side on which the anode pad 112 or the cathode pad 114 is provided. In other words, the second part 72 is a part positioned between the poly runner 133, and the anode pad 112 or the cathode pad 114.

when the interlayer dielectric film 38 is exposed upwards, moisture is absorbed. By providing the metal electrode 62, it is possible to suppress the exposure of the interlayer dielectric film 38. An inside end portion of the gate runner 130 may entirely overlap with the metal electrode 62 in the top view.

A distance between the metal electrode 62, and the anode pad 112 or the cathode pad 114 may be 50μm or less, may be 40μm or less, or may be 30μm or less. The distance may be 5 μm or more.

The present example describes a case where the metal electrode 62 is at the same potential as that of the source electrode 52; however, the metal electrode 62 may also be at the same potential as that of the cathode pad 114. In this case, the metal electrode 62 may be separated from the source electrode 52. The metal electrode 62 may be connected to the cathode pad 114. The metal electrode 62 may not be floating in potential. Note that the semiconductor device 100 may not include the metal electrode 62. It should be noted that in a case where the metal electrode 62 is set to the same potential as that of the cathode pad 114, the metal electrode 62 may be connected to the source electrode 52.

The gate runner 130 has an outer peripheral runner portion and a temperature sense runner portion. This distinction is made in an arrangement of the gate runner 130 in the top view. The outer peripheral runner portion is arranged between the active portion 120 and an end portion of the semiconductor substrate 10. The outer peripheral runner portion may surround the active portion 120. The outer peripheral runner portion may also surround each pad in addition to the active portion 120. The outer peripheral runner portion in the region A may be a part of the gate runner 130 which is arranged along the edge termination structure portion 90. In addition, in the second direction, the gate runner 130 (the poly runner 133) provided between the anode pad 112 and the cathode pad 114, and the active portion 120 may be included in the outer peripheral runner portion, and the gate runner 130 arranged along the gate pad 116 may be included in the outer peripheral runner portion.

The temperature sense runner portion surrounds the anode pad 112 and the cathode pad 114. The temperature sense runner portion may be the gate runner 130 which is the closest to the anode pad 112 and the cathode pad 114, in the gate runners 130 surrounding the anode pad 112 and the cathode pad 114. The temperature sense runner portion may also surround the temperature sense diode 115.

The outer peripheral runner portion may have a part overlapping with the temperature sense runner portion. In FIG. 5, a part of the gate runner 130 which is arranged along the edge termination structure portion 90 is the outer peripheral runner portion, and is also the temperature sense runner portion. In addition, in the second direction, the gate runner 130 (the poly runner 133) provided between the anode pad 112 and the cathode pad 114, and the active portion 120 is also the outer peripheral runner portion, and is also the temperature sense runner portion.

The outer peripheral runner portion may include a stacked runner obtained by stacking the metal runner 131 and the poly runner 133. At least a part of the outer peripheral runner portion may be the stacked runner, or the entire outer peripheral runner portion may be the stacked runner. In the present example, the part of the gate runner 130 which is arranged along the edge termination structure portion 90, and a part arranged along the gate pad 116 are the stacked runner. It should be noted that among the gate runners 130, the poly runner 133 facing the stacked portion in a width direction perpendicular to the extension direction of the metal runner 131, may also be included in the stacked runner. In other words, in the entire width direction perpendicular to the extension direction of the gate runner, a part that does not include the metal runner 131 may be a non-stacked runner.

At least a part of the temperature sense runner portion may be the non-stacked runner which includes the poly runner 133 and does not include a metal runner 131. In the present example, the gate runner 130 provided between the anode pad 112 and the cathode pad 114, and the active portion 120 in the second direction is the non-stacked runner. This makes it easy for the metal electrode 62 to surround the anode pad 112 and the cathode pad 114. The first part 71 of the metal electrode 62 may overlap with the non-stacked runner. The second part 72 of the metal electrode may extend to an inside further than the non-stacked runner.

In the present example, another part of the temperature sense runner portion is the stacked runner. In other words, the temperature sense diode 115, the anode pad 112, the cathode pad 114 are surrounded by the poly runner 133, and are not surrounded by the metal runner 131. On the other hand, the active portion 120 is surrounded by both of the poly runner 133 and the metal runner 131.

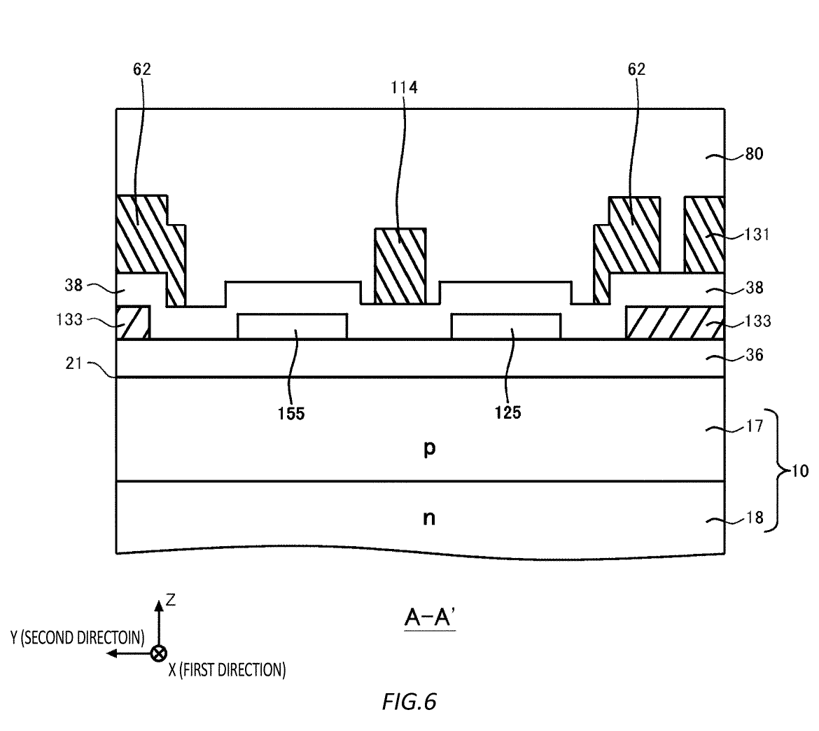

FIG. 6 is a cross-sectional view showing an example of a line A-A' in FIG. 5. A cross section A-A' is a YZ cross section passing through the main diode 155, the cathode pad 114, and the protection diode 125. Note that in FIG. 6, a lower surface side of the semiconductor substrate 10 is omitted. In the cross section A-A', the semiconductor device 100 includes the semiconductor substrate 10, the field oxide film 36, the main diode 155, the protection diode 125, the poly runner 133, the metal runner 131, the interlayer dielectric film 38, the cathode pad 114, the metal electrode 62, and the protective film 80.

The semiconductor substrate 10 in the present example has a drift region 18 of the n type, and a well region 17 of the p type provided between the drift region 18 and the upper surface 21. Note that a region of the n type may be provided in a part in contact with the upper surface 21 of the semiconductor substrate 10. A thickness of the semiconductor substrate 10 may be 50 μm or more and 500 μm or less, and is 98 μm as an example.

The field oxide film 36 is provided on the upper surface 21 of the semiconductor substrate 10. The main diode 155, the protection diode 125, the cathode pad 114, the poly runner 133, and the like are provided above the field oxide film 36, and are insulated from the semiconductor substrate 10. The anode pad 112 is also provided above the field oxide film 36 in another cross section. A thickness of the field oxide film 36 may be 0.1 μm or more and 2.0 μm or less, and is 1.1 μm as an example.

The interlayer dielectric film 38 is provided above the upper surface 21 of the semiconductor substrate 10. In the present example, the interlayer dielectric film 38 is provided above the field oxide film 36, the poly runner 133, the main diode 155, and the protection diode 125. A thickness of the interlayer dielectric film 38 is 0.65 μm as an example. A thickness of the poly runner 133 may be 0.3 μm or more and 1.3 μm or less, and is 0.8 μm as an example.

Above the interlayer dielectric film 38, the metal electrode 62, the cathode pad 114, and the metal runner 131 are provided. The metal electrode 62 is provided, in the second direction, to extend to a vicinity of the main diode 155 and the protection diode 125, further than the poly runner 133. Thicknesses of the metal electrode 62, the cathode pad 114, and the metal runner 131 may be 3 μm or more and 7 μm or less, and the thickness is 5.5 μm as an example. The protective film 80 is provided above the interlayer dielectric film 38, the metal electrode 62, the cathode pad 114, and the metal runner 131.

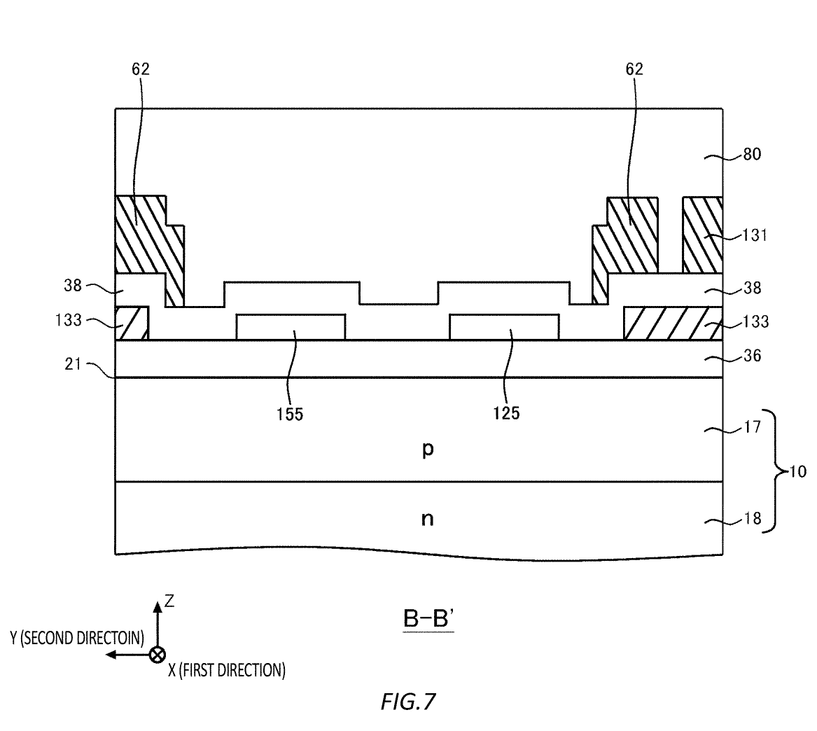

FIG. 7 is a cross-sectional view showing an example of a line B-B' in FIG. 5. A cross section B-B' is a YZ cross section passing through the main diode 155 and the protection diode 125. Note that in FIG. 7, the lower surface side of the semiconductor substrate 10 is omitted. The cross section B-B' is different from the cross section A-A' in that the cathode pad 114 is not provided between the main diode 155 and the protection diode 125. Another location is the same as that of the cross section A-A'.

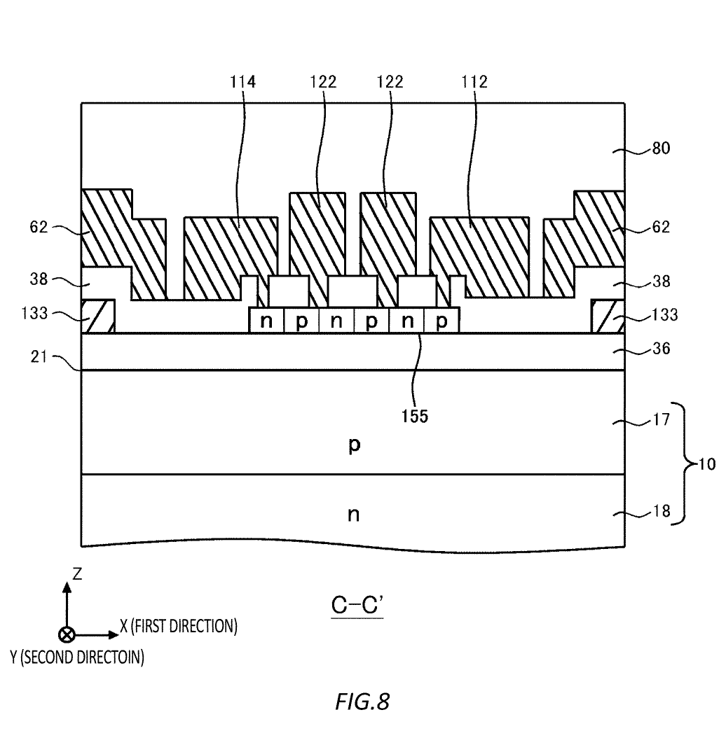

FIG. 8 is a cross-sectional view showing an example of a line C-C' in FIG. 5. A cross section C-C' is an XZ cross section passing through the main diode 155. Note that in FIG. 8, the lower surface side of the semiconductor substrate 10 is omitted. A configuration below the field oxide film 36 is the same as that of FIG. 6, and thus the description is omitted.

The anode pad 112, the cathode pad 114, and the connection metal 122 are connected to the main diode 155 via the contact holes provided in the interlayer dielectric film 38. The main diode 155 in the present example has three p-n junctions between the anode pad 112 and the cathode pad 114. The connection metal 122 connects adjacent p-n junctions in series.

The metal electrode 62 in the present example is provided, in the first direction, to extend to vicinities of the anode pad 112 and the cathode pad 114, further than the poly runner 133. Note that the metal electrode 62 in the present example is not connected to the anode pad 112 and the cathode pad 114.

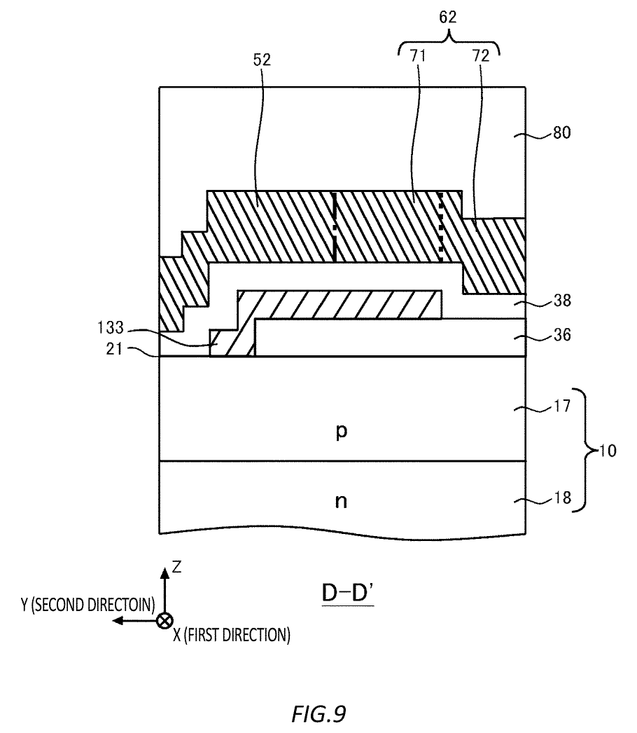

FIG. 9 is a cross-sectional view showing an example of a line D-D' in FIG. 5. A cross section D-D' is a YZ cross section passing through the poly runner 133 provided between the anode pad 112 and the cathode pad 114, and the active portion 120. Note that in FIG. 9, the lower surface side of the semiconductor substrate 10 is omitted.

In the second direction, an end portion of the field oxide film 36 may be positioned below the gate runner 130 provided between the anode pad 112 and the cathode pad 114, and the active portion 120. The gate runner 130 may be the non-stacked runner. The end portion of the field oxide film 36 in the present example is positioned, in the second direction, below the poly runner 133 provided between the anode pad 112 and the cathode pad 114, and the active portion 120. In other words, in the second direction, the end portion of the field oxide film 36 is covered by the poly runner 133. This makes it possible for a step to be gentle at the end portion of the field oxide film 36.

When a gate trench is provided in the active portion 120, an extension direction of the gate trench may be in the first direction. That is, the gate runner 130 provided between the anode pad 112 and the cathode pad 114, and the active portion 120 may not be connected to the gate trench of the active portion.

In FIG. 9, a boundary between the source electrode 52 and the metal electrode 62 is indicated by a dash- single dotted line. In addition, a boundary between the first part 71 and the second part 72 of the metal electrode 62 is indicated by a dotted line. Note that as described above, these boundaries may be boundaries for convenience.

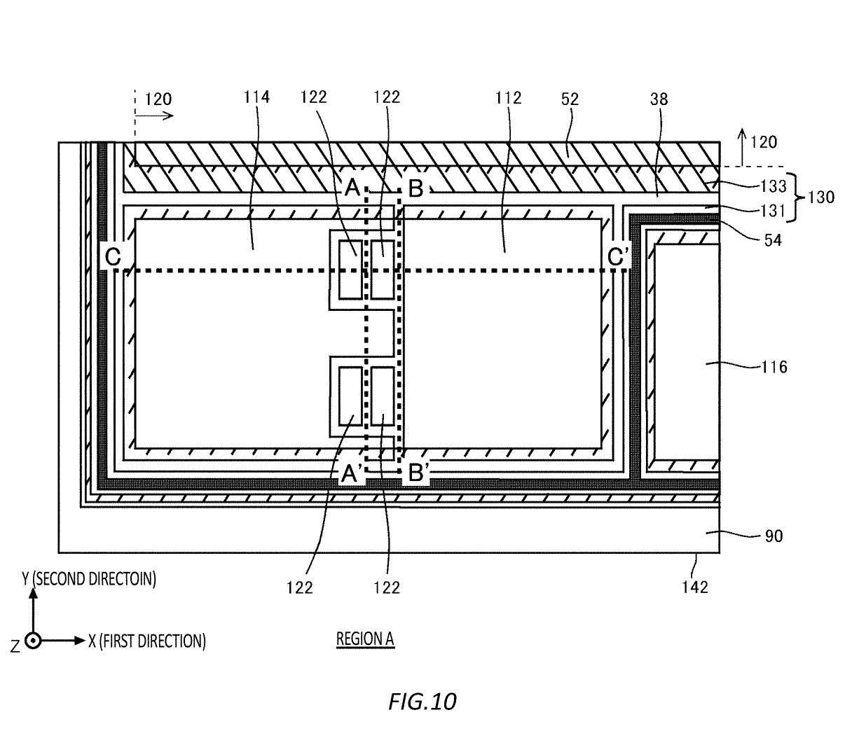

FIG. 10 is a view showing an arrangement of electrodes in the region A of the semiconductor device according to a comparative example. In addition to FIG. 3, FIG. 10 shows the arrangement of the source electrode 52 with hatching. Note that in FIG. 10, the temperature sense diode 115 is omitted. In addition, the poly runner 133 is hatched only at the end portion.

The source electrode 52 in the present example is provided partway through the poly runner 133, in the second direction, between the active portion 120, and the anode pad 112 and the cathode pad 114. The semiconductor device in the present example does not include the metal electrode 62 surrounding the anode pad 112 and the cathode pad 114.

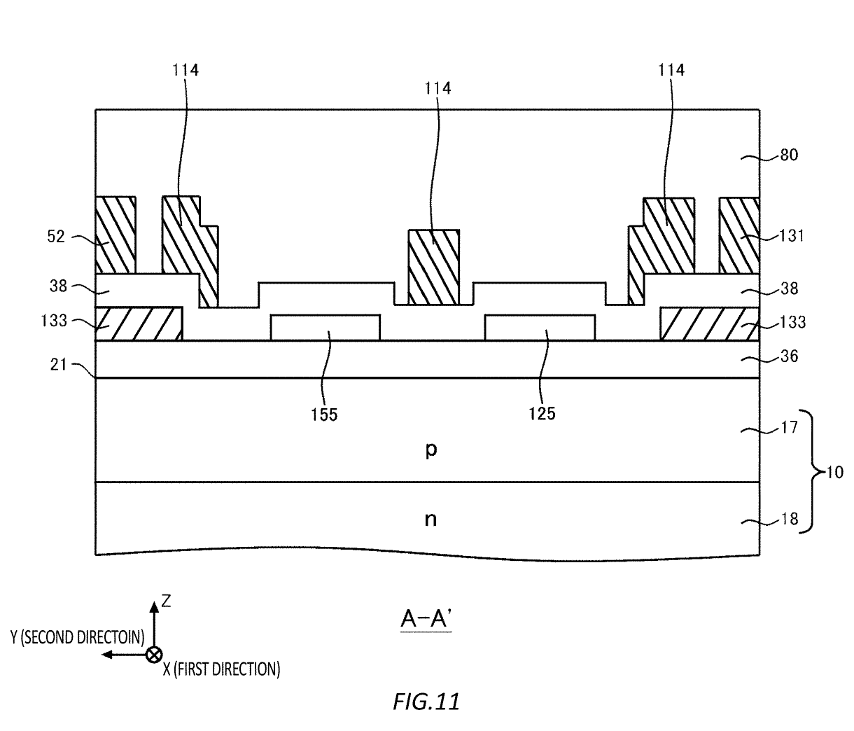

FIG. 11 is a cross-sectional view showing an example of a line A-A' in FIG. 10. A cross section A-A' is a YZ cross section passing through the main diode 155, the cathode pad 114, and the protection diode 125. Note that in FIG. 11, the lower surface side of the semiconductor substrate 10 is omitted.

The cathode pad 114 is provided above the end portion of the poly runner 133 in the second direction in the present example. In addition, the source electrode 52 separated from the cathode pad 114 is provided above the poly runner 133. Other parts are the same as those of the cross section A-A' shown in FIG. 6.

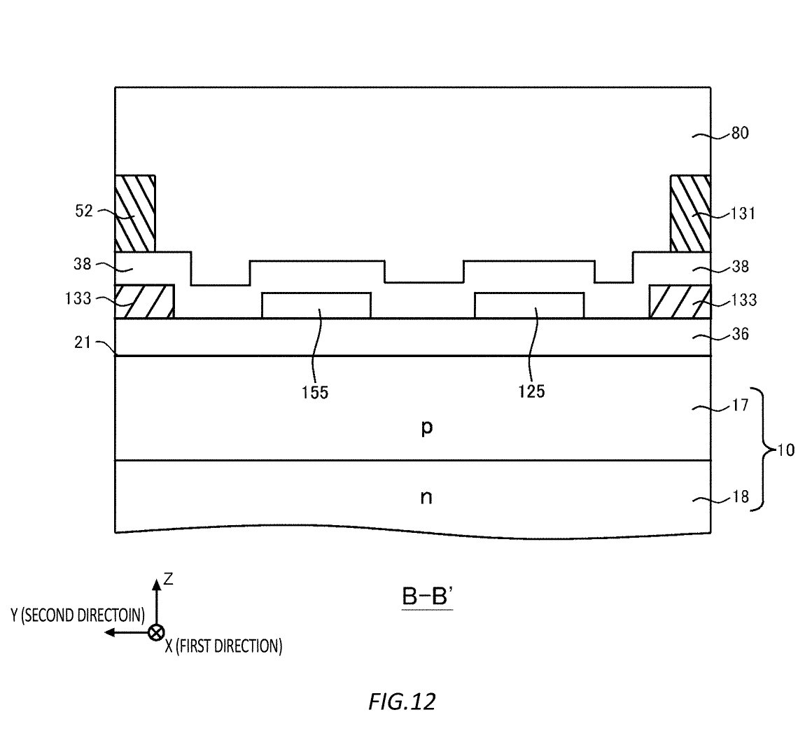

FIG. 12 is a cross-sectional view showing an example of a line B-B' in FIG. 10. A cross section B-B' is a YZ cross section passing through the main diode 155 and the protection diode 125. Note that in FIG. 12, the lower surface side of the semiconductor substrate 10 is omitted.

The semiconductor device in the present example does not include the metal electrode 62. The source electrode 52 is provided above the poly runner 133 in the present example. Other parts are the same as the cross section B-B' shown in FIG. 7.

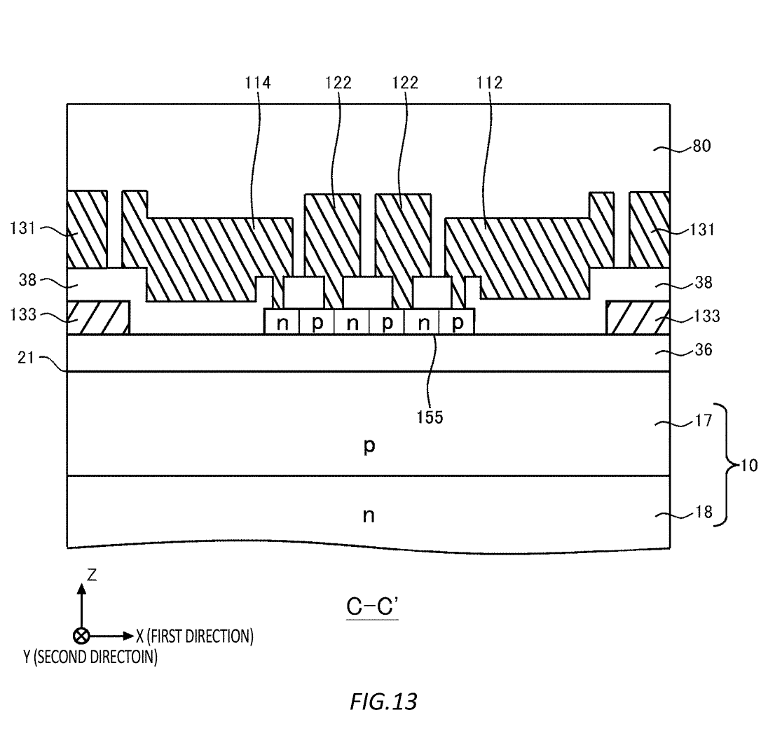

FIG. 13 is a cross-sectional view showing an example of a line C-C' in FIG. 10. A cross section C-C' is an XZ cross section passing through the main diode 155. Note that in FIG. 13, the lower surface side of the semiconductor substrate 10 is omitted.

The anode pad 112 or the cathode pad 114 is provided above the end portion of the poly runner 133 in the first direction in the present example. In addition, the semiconductor device in the present example does not include the metal electrode 62. Other parts are the same as the cross section B-B' shown in FIG. 7.

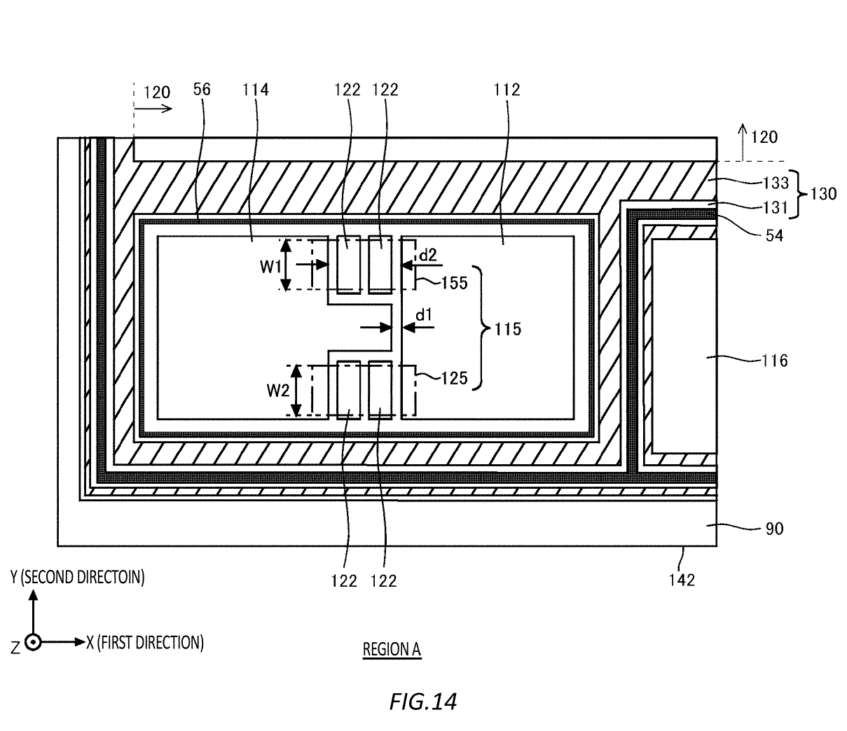

FIG. 14 is an enlarged view of the region A in FIG. 1. The region A is a region around the anode pad 112 and the cathode pad 114. Note that similar to FIG. 2, FIG. 14 omits illustrations of the interlayer dielectric film 38, the source electrode 52, and the metal electrode 62. The description of a configuration similar to that of FIG. 2 is omitted.

In the semiconductor device 100 in the present example, a contact hole 56 is formed in a dielectric film. The dielectric film may be the field oxide film 36 as shown in FIG. 6 or the like, may be the interlayer dielectric film 38, or may be both of the field oxide film 36 and the interlayer dielectric film 38. The metal electrode 62 is connected to the upper surface 21 of the semiconductor substrate 10 through the contact hole 56. In FIG. 14, a position at which the contact hole 56 is provided is indicated with dark hatching.

The contact hole 56 is provided between the gate runner 130, and the anode pad 112 or the cathode pad 114. The contact hole 56 may be provided between the gate runner 130 and the temperature sense diode 115, or may be provided between the gate runner 130 and the connection metal 122.

The contact hole 56 may be provided to be longer than one side of the anode pad 112, and may be provided to be longer than one side of the cathode pad 114. The contact hole 56 in the present example surrounds the anode pad 112 and the cathode pad 114. In addition, the contact hole 56 in the present example surrounds the temperature sense diode 115 and the connection metal 122.

The gate runner 130 may not be provided in a range surrounded by the contact hole 56. In other words, a gate structure may not be provided in the range surrounded by the contact hole 56. The gate structure is a part that forms a channel and causes the current to flow when the gate voltage is applied from the gate pad 116. An example of the gate structure includes a trench gate structure or a planar gate structure. In other words, the transistor portion may not be provided in the region surrounded by the contact hole 56. The temperature sense diode 115 is provided in the region surrounded by the contact hole 56 In the present example. The transistor portion may be provided in the active portion 120.

The contact hole 56 may be surrounded by the gate runner 130. In the present example, the contact hole 56 is surrounded by the poly runner 133. The active portion 120 may not be provided between the poly runner 133 and the contact hole 56.

A shortest distance between the anode pad 112 and the cathode pad 114 is set as d1. The distance d1 may be 50 μm or less, may be 40 μm or less, or may be 30 μm or less. The distance may be 5 μm or more. In the present example, the distance is 15 μm or more and 20 μm or less. When the connection metal 122 is provided between the anode pad 112 and the cathode pad 114, a distance d2 between the anode pad 112 and the cathode pad 114 which face each other across the connection metal 122 may be 250 μm or less. The distance may be 120 μm or more. In the present example, the distance is 200 μm or more and 210 μm or less. For example, when a silicon carbide semiconductor substrate is used as the semiconductor substrate 10, it is often the case that a chip size is reduced, from a viewpoint of a yield rate due to a crystal defect, an advantage in physical property compared to silicon, and a viewpoint of a cost benefit. In order to effectively use the active portion 120, the temperature sense diode 115 is provided between the pads outside the active portion 120 (in the present example, between the anode pad 112 and the cathode pad 114). Note that the chip size is small, and thus the distances d1 and d2 between the pads also become small. Note that the semiconductor substrate 10 is not limited to the silicon carbide semiconductor substrate. The semiconductor substrate 10 may be a silicon semiconductor substrate or a wide bandgap semiconductor substrate of gallium nitride or the like.

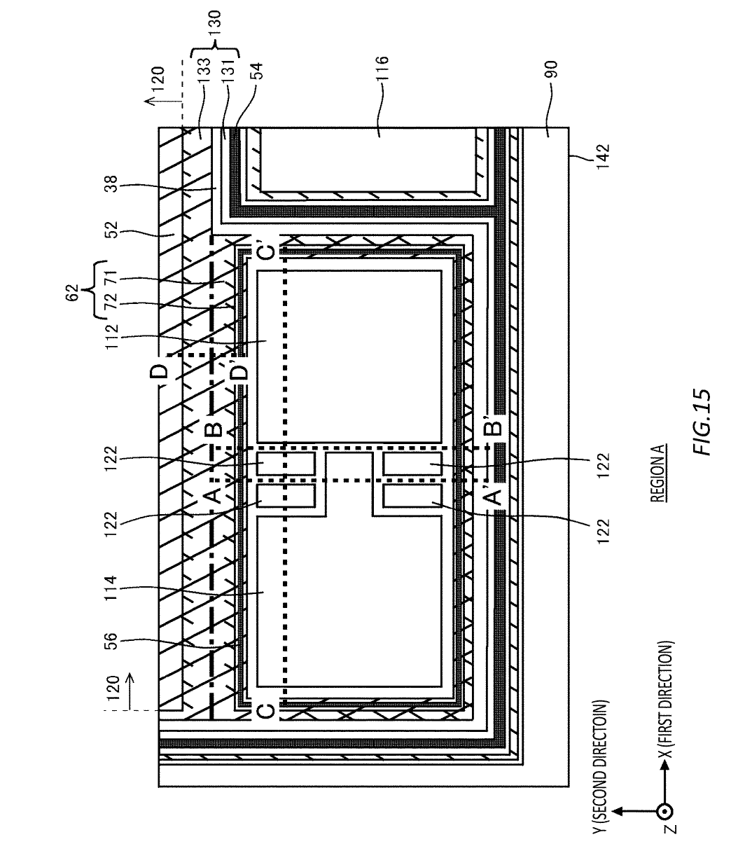

FIG. 15 is a view showing an arrangement of electrodes in the region A. In addition to FIG. 14, FIG. 15 shows the arrangement of the interlayer dielectric film 38, the source electrode 52, and the metal electrode 62. The hatching or the like of each configuration is similar to that of FIG. 5. In the present example as well, the position of the contact hole 56 is indicated with dark hatching.

The contact hole 56 is provided at a position overlapping with the second part 72 of the metal electrode 62 which is provided on an inside further than the gate runner 130. In this manner, the metal electrode 62 is connected to the upper surface 21 of the semiconductor substrate 10. The metal electrode 62 may be connected to the source electrode 52. That is, by providing the contact hole 56, it is possible to electrically connect the upper surface 21 of the semiconductor substrate 10 to the source electrode 52, around the temperature sense diode 115 (hereinafter referred to as a source contact). This makes it possible to extract a displacement current described below, and makes it possible to stabilize a potential below the temperature sense diode 115 for the displacement current not to be concentrated.

As a definition of the active portion 120, in a case of using a region in which the source electrode 52 periodically comes into contact with the semiconductor substrate 10, the contact may not include the contact between the metal electrode 62 and the semiconductor substrate 10 via the contact hole 56. In addition, the active portion 120 may be a region in which a source region of the n type having a higher doping concentration than that of the drift region 18 is periodically or continuously exposed on the upper surface 21 of the semiconductor substrate 10. Both ends of the region, in the X axis direction, in which the source region is exposed on the upper surface 21 of the semiconductor substrate 10, may be set as both ends of the active portion 120 in the X axis direction. Both ends of the region, in the Y axis direction, in which the source region is exposed on the upper surface 21 of the semiconductor substrate 10, may be set as both ends of the active portion 120 in the Y axis direction. The active portion 120 may be a rectangular region that is defined by both ends in the X axis direction and both ends in the Y axis direction. The contact hole 56 in the present example is entirely provided on an outside further than the active portion 120.

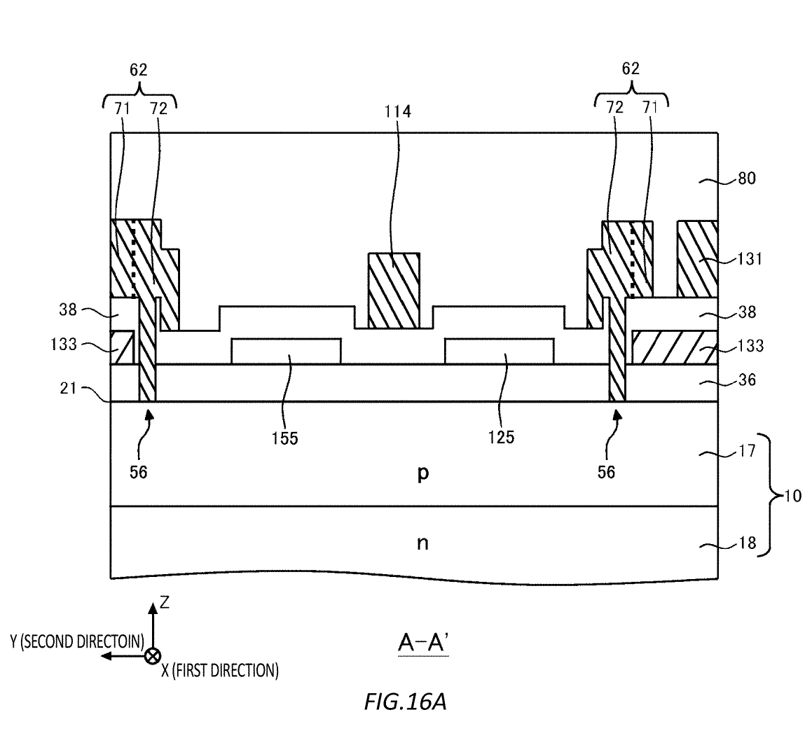

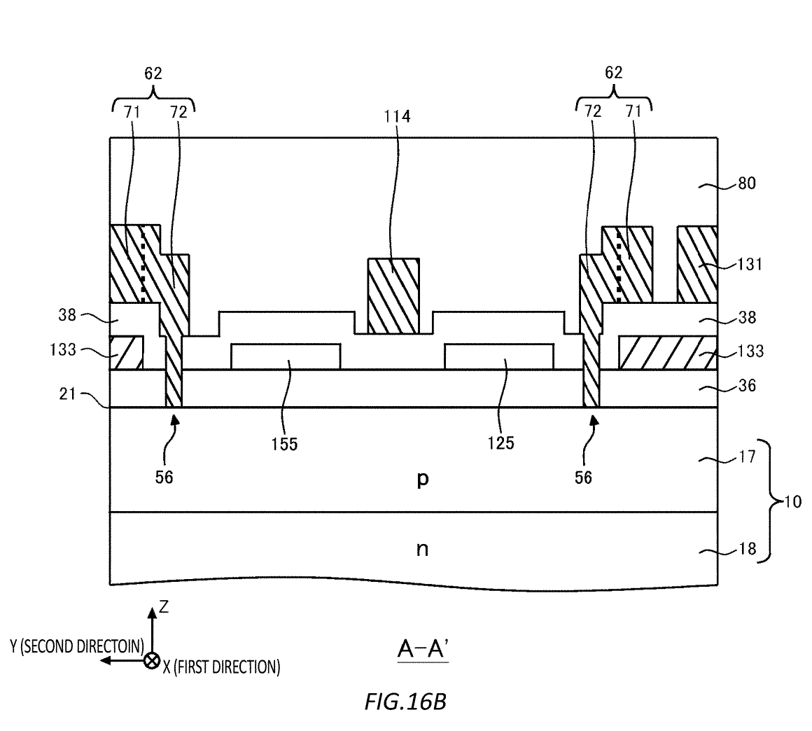

FIG. 16A is a cross-sectional view showing an example of a line A-A' in FIG. 15. A cross section A-A' is a YZ cross section passing through the main diode 155, the cathode pad 114, and the protection diode 125. Note that in FIG. 16A, the lower surface side of the semiconductor substrate 10 is omitted. FIG. 16A is different from the cross section A-A' of FIG. 6 in that the contact hole 56 is formed in the dielectric film. In addition, FIG. 16A shows the boundary between the first part 71 and the second part 72 of the metal electrode 62.

The dielectric film is provided between the upper surface 21 of the semiconductor substrate 10 and the metal electrode 62. The dielectric film in the present example is between the field oxide film 36 and the interlayer dielectric film 38. The field oxide film 36 is provided on the upper surface 21 of the semiconductor substrate 10. The interlayer dielectric film 38 is provided above the field oxide film 36 and the gate runner 130 (in the present example, the poly runner 133). The contact hole 56 in the present example is formed to pass through the interlayer dielectric film 38 and the field oxide film 36.

The interlayer dielectric film 38 in the present example has a shape of an undulation reflecting a shape of the poly runner 133. That is, in a vicinity of the poly runner 133, an upper surface of the interlayer dielectric film 38 is pushed upwards (a positive side of the Z axis) by the poly runner 133 (hereinafter referred to as a protrusion part). In addition, in a case of being apart from the poly runner 133, the upper surface of the interlayer dielectric film 38 is recessed downwards (a negative side of the Z axis) (hereinafter referred to as a recess part). A similar undulation is also formed by the main diode 155 and the protection diode 125. The contact hole 56 in the present example is provided in the protrusion part of the interlayer dielectric film 38.

The second part 72 of the metal electrode 62 is connected to the upper surface 21 of the semiconductor substrate 10 via the contact hole 56. In the cross section A-A’ in the present example, the connections are made at two locations across the main diode 155 and the protection diode 125 in the Y axis direction. Inside the contact hole 56, a contact plug of tungsten or the like, or a barrier metal of titanium or the like may be formed.

The second part 72 may be connected to the well region 17 via the contact hole 56. In other words, the contact hole 56 may be provided above the well region 17. The contact hole 56 may be entirely provided above the well region 17. The well region 17 may surround the active portion 120 in the top view.

FIG. 16B is a cross-sectional view showing another example of the line A-A' in FIG. 15. In the present example, the position of the contact hole 56 is different from that in the case of FIG. 16A. The contact hole 56 in the present example is formed in the recess part of the interlayer dielectric film 38. By forming the contact hole 56 in such a position, the source contact can also be made in the vicinity of the temperature sense diode 115.

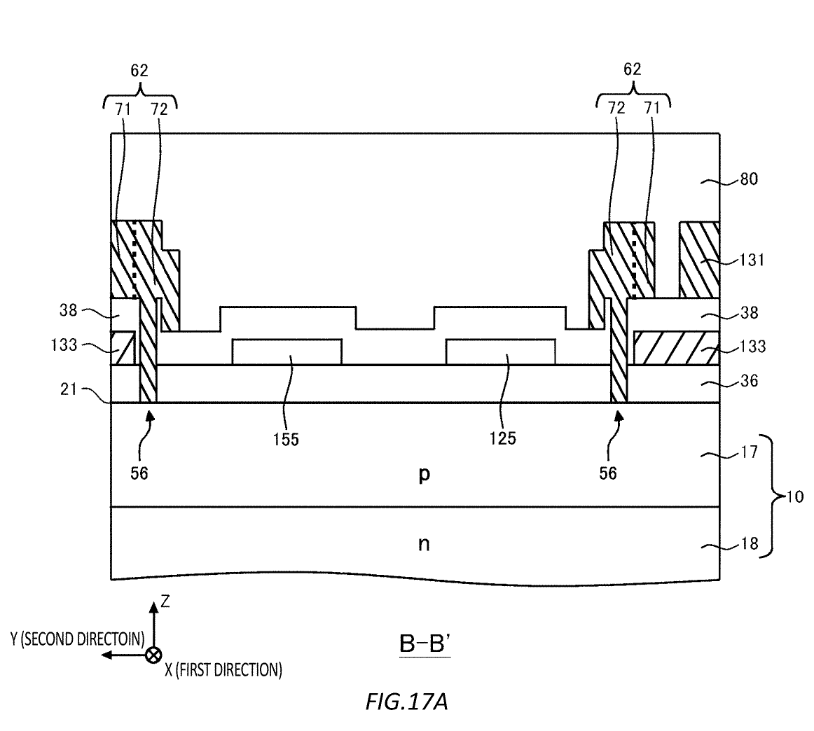

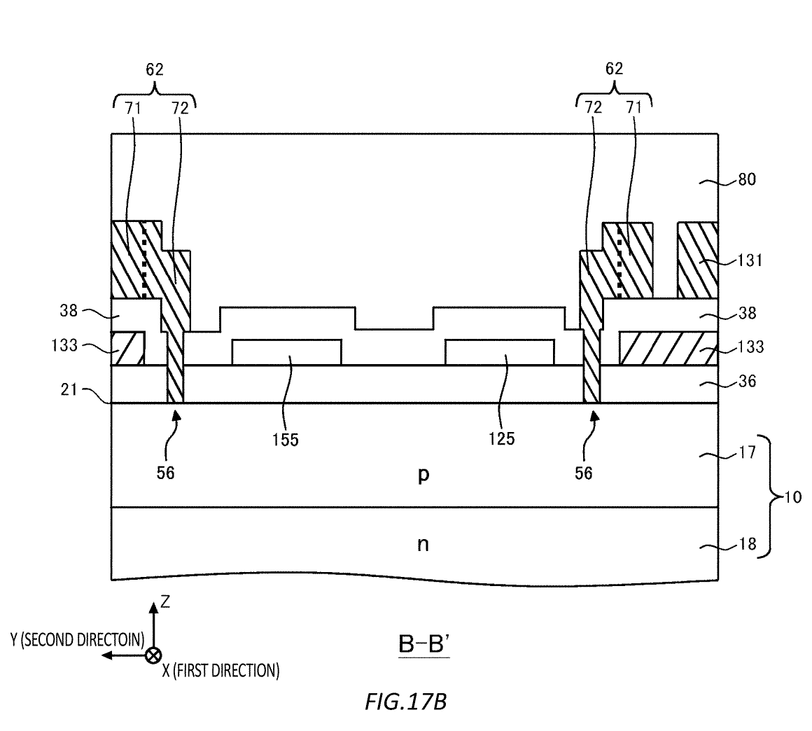

FIG. 17A is a cross-sectional view showing an example of a line B-B' in FIG. 15. A cross section B-B' is a YZ cross section passing through the main diode 155 and the protection diode 125. Note that in FIG. 17A, the lower surface side of the semiconductor substrate 10 is omitted. FIG. 17A is different from the cross section B-B’ of FIG. 7 in that the contact hole 56 is formed in the dielectric film. In addition, FIG. 17A shows the boundary between the first part 71 and the second part 72 of the metal electrode 62. The contact hole 56 in the present example is formed on the protrusion part of the interlayer dielectric film 38.

FIG. 17B is a cross-sectional view showing another example of the line B-B' in FIG. 15. The contact hole 56 in the present example is formed in the recess part of the interlayer dielectric film 38. By forming the contact hole 56 in such a position, the source contact can also be made in the vicinity of the temperature sense diode 115.

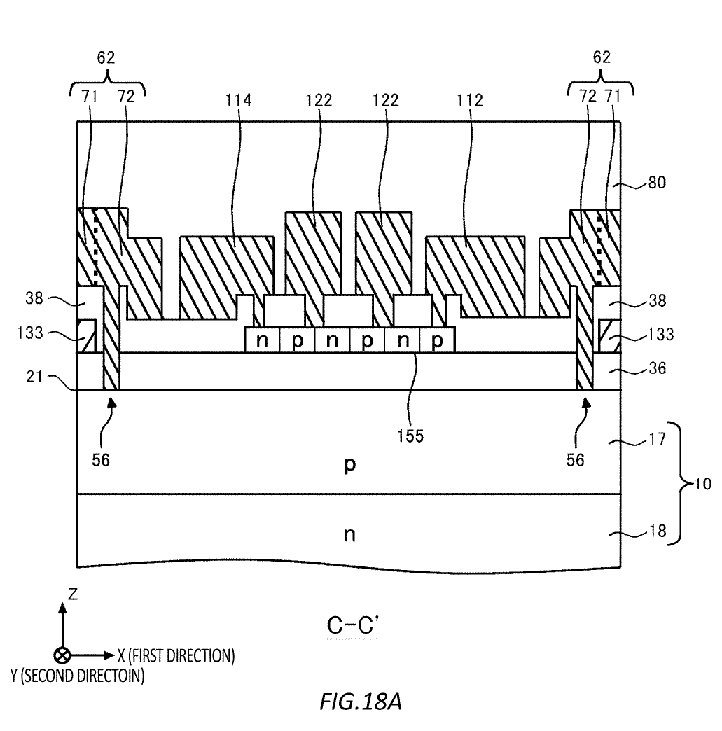

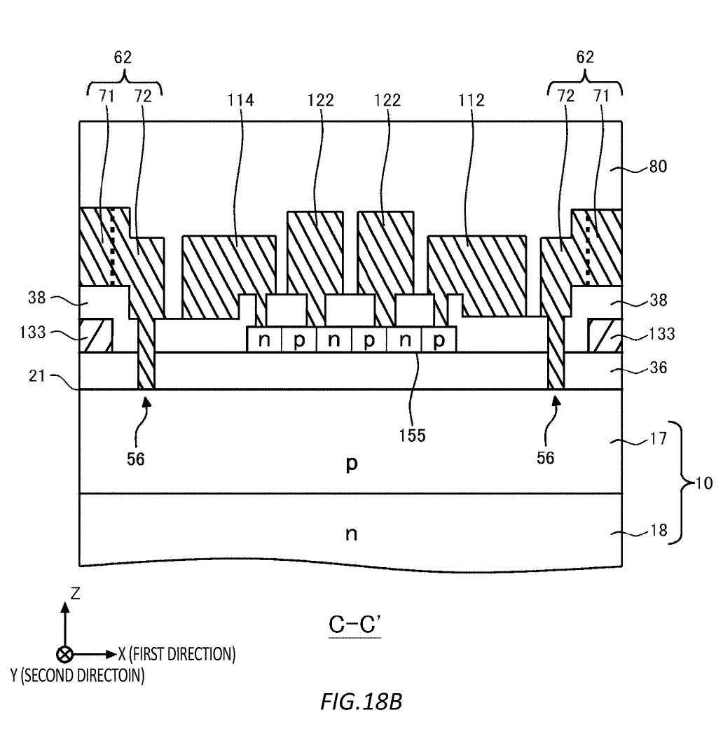

FIG. 18A is a cross-sectional view showing an example of a line C-C' in FIG. 15. A cross section C-C' is an XZ cross section passing through the main diode 155. Note that in FIG. 18A, the lower surface side of the semiconductor substrate 10 is omitted. FIG. 18A is different from the cross section C-C' in FIG. 8 in that the contact hole 56 is formed in the dielectric film. In addition, FIG. 18A shows the boundary between the first part 71 and the second part 72 of the metal electrode 62. The contact hole 56 in the present example is formed on the protrusion part of the interlayer dielectric film 38.

FIG. 18B is a cross-sectional view showing another example of the line C-C' in FIG. 15. The contact hole 56 in the present example is formed in the recess part of the interlayer dielectric film 38. By forming the contact hole 56 in such a position, the source contact can also be made in the vicinity of the temperature sense diode 115.

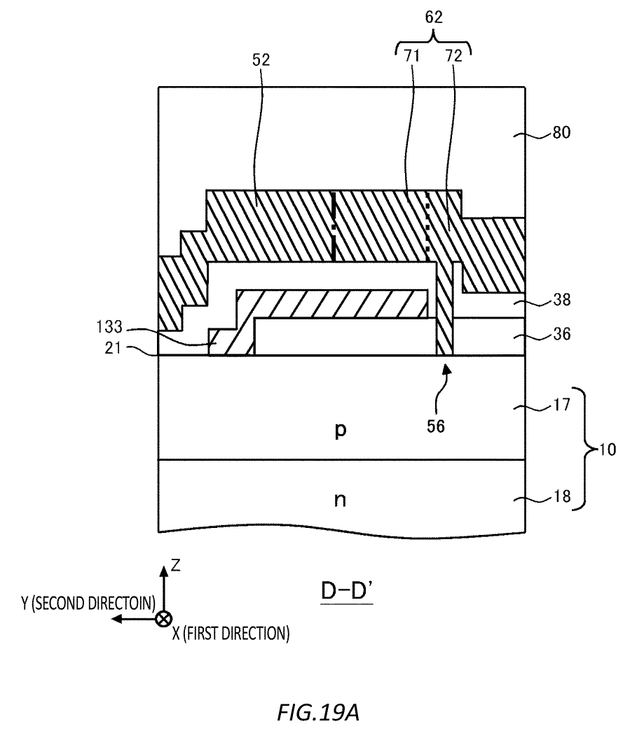

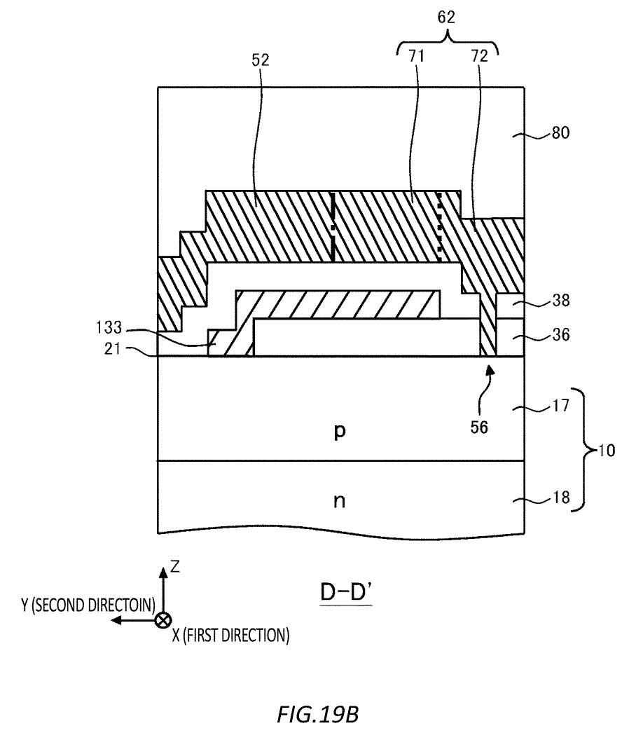

FIG. 19A is a cross-sectional view showing an example of a line D-D' in FIG. 15. A cross section D-D' is a YZ cross section passing through the poly runner 133 provided between the anode pad 112 and the cathode pad 114, and the active portion 120. Note that in FIG. 9, the lower surface side of the semiconductor substrate 10 is omitted. FIG. 19A is different from the cross section D-D' in FIG. 9 in that the contact hole 56 is formed in the dielectric film. The contact hole 56 in the present example is formed on the protrusion part of the interlayer dielectric film 38.

FIG. 19B is a cross-sectional view showing another example of the line D-D' in FIG. 15. The contact hole 56 in the present example is formed in the recess part of the interlayer dielectric film 38. By forming the contact hole 56 in such a position, the source contact can also be made in the vicinity of the temperature sense diode 115. It should be noted that FIG. 16A to FIG. 19B describe the examples in which the contact hole 56 is formed in the protrusion part or the recess part of the interlayer dielectric film 38, but the contact hole 56 may be formed to straddle the protrusion part and the recess part of the interlayer dielectric film. In the example of the present invention, regardless of a position at which the contact hole 56 is formed, the metal electrode 62 covers the step of the protrusion part and the recess part of the interlayer dielectric film 38 by the poly runner 133, similar to FIG. 5 to FIG. 9, and thus it is possible to suppress a short circuit between the anode pad 112 and the cathode pad 114.

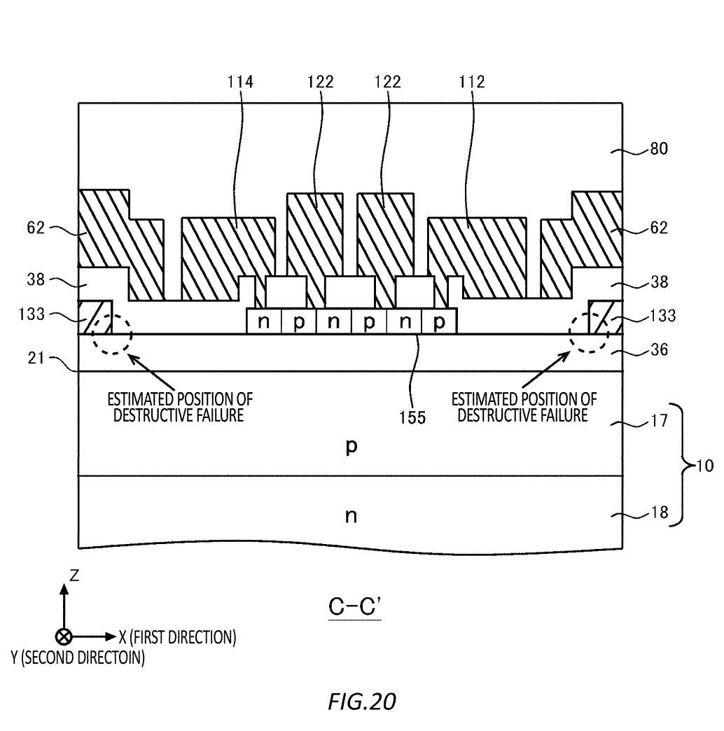

FIG. 20 is a view showing a cross section C-C' of the semiconductor device 100 in a reference example. The semiconductor device 100 in the reference example is not provided with the contact hole 56. When the temperature sense diode 115 is arranged between signal pads without the contact hole 56 being provided as in the present example, there may be a case where a dvdt destructive failure occurs around the temperature sense diode 115 due to a high speed switching operation. This is thought to be because the poly runner 133 is not provided below the temperature sense diode 115, and thus junction capacitance becomes small, a potential easily rises, and a displacement current is concentrated. The destructive failure is estimated to occur at the end portion of the poly runner 133 on a temperature sense diode 115 side. In FIG. 20, the relevant end portion is indicated by a dotted line.

By providing the contact hole 56 as shown in FIG. 14, FIG. 15, and the like, it is possible to extract the displacement current, and it is possible for the displacement current not to be concentrated around the temperature sense diode 115. Therefore, it is possible to improve the dvdt destructive failure withstand capability, and a high speed switching operation is possible.

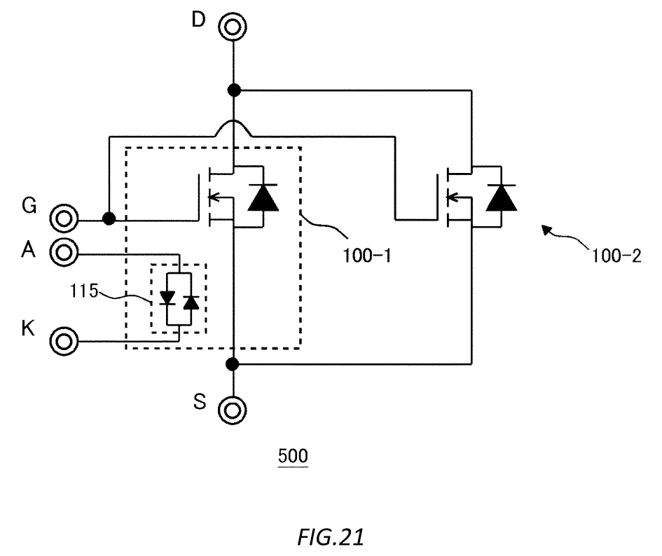

FIG. 21 is a circuit diagram of a semiconductor circuit 500 including the semiconductor device 100 of an example. The semiconductor circuit 500 includes a plurality of semiconductor devices 100 connected in parallel. The semiconductor circuit 500 in the present example includes two semiconductor devices 100 which are a semiconductor device 100-1 and a semiconductor device 100-2 that are connected in parallel.

At least one semiconductor device 100 of the plurality of semiconductor devices 100 may have the temperature sense diode 115. At least one semiconductor device 100 of the plurality of semiconductor devices 100 may not have the temperature sense diode 115. In the present example, the semiconductor device 100-1 has the temperature sense diode 115, and the semiconductor device 100-2 does not have the temperature sense diode 115. In this manner, it is possible that the semiconductor device 100 having the temperature sense diode 115 detects a temperature and that another semiconductor device 100 increases the area of the active portion 120, or reduces the chip size. Only one semiconductor device 100 of the plurality of semiconductor devices 100 may have the temperature sense diode 115.

While the present invention has been described by way of the embodiments, the technical scope of the present invention is not limited to the above-described embodiments. It is apparent to persons skilled in the art that various alterations or improvements can be made to the above-described embodiments. The embodiment described above is not limited to a silicon carbide semiconductor substrate, and may be a silicon substrate or a wide bandgap semiconductor substrate of gallium nitride or the like. It is also apparent from description of the claims that the embodiments to which such changes or improvements are made may be included in the technical scope of the present invention.

The present specification and the drawings also disclose inventions related to the respective following clauses.

[Clause 1] A semiconductor device including: a semiconductor substrate which has an upper surface; a temperature sense diode which is arranged above the upper surface of the semiconductor substrate; an anode pad which is arranged above the upper surface of the semiconductor substrate, and which is connected to an anode of the temperature sense diode; a cathode pad which is arranged above the upper surface of the semiconductor substrate, and which is connected to a cathode of the temperature sense diode; a gate pad which is arranged above the upper surface of the semiconductor substrate; and a gate runner which is arranged above the upper surface of the semiconductor substrate, and which is connected to the gate pad, in which an entire region between the anode pad and the cathode pad does not overlap with the gate runner.

[Clause 2] The semiconductor device according to clause 1, in which the anode pad and the cathode pad do not overlap with the gate runner.

[Clause 3] The semiconductor device according to clause 1, in which the gate runner is polysilicon.

[Clause 4] The semiconductor device according to clause 1, in which the temperature sense diode is arranged in a region between the anode pad and the cathode pad.

[Clause 5] The semiconductor device according to any one of clauses 1 to 4, in which the gate runner surrounds the temperature sense diode, the anode pad, and the cathode pad.

[Clause 6] The semiconductor device according to clause 5, further including: a metal electrode which is arranged above the upper surface of the semiconductor substrate, in which the metal electrode surrounds the anode pad and the cathode pad, and the metal electrode has, a first part which overlaps with the gate runner, and a second part which extends to an inside further than the gate runner.

[Clause 7] The semiconductor device according to clause 6, in which an inside end portion of the gate runner entirely overlap with the metal electrode in a top view.

[Clause 8] The semiconductor device according to clause 6, in which the metal electrode is an electrode of a source potential.

[Clause 9] The semiconductor device according to clause 6, in which the metal electrode is at a same potential as that of the cathode pad.

[Clause 10] The semiconductor device according to any one of clauses 1 to 4, in which the semiconductor substrate has an active portion that is a region in which a semiconductor element is formed, the anode pad and the cathode pad are arranged along a first direction, in a second direction perpendicular to the first direction in a top view, the anode pad and the cathode pad face the active portion, and the gate runner is provided between the anode pad and the cathode pad, and the active portion.

[Clause 11] The semiconductor device according to clause 10, further including: a field oxide film which is provided on the upper surface of the semiconductor substrate, in which the temperature sense diode, the anode pad, and the cathode pad are provided above the field oxide film, and an end portion of the field oxide film is positioned below the gate runner provided between the anode pad and the cathode pad, and the active portion, in the second direction.

[Clause 12] The semiconductor device according to any one of clauses 1 to 4, in which the semiconductor substrate has an active portion that is a region in which a semiconductor element is formed, the gate runner has, an outer peripheral runner portion which surrounds the active portion, and a temperature sense runner portion which surrounds the anode pad and the cathode pad, the outer peripheral runner portion includes a stacked runner in which a metal runner and a poly runner are stacked, and at least a part of the temperature sense runner portion is a non-stacked runner which includes the poly runner and does not include the metal runner.

[Clause 13] The semiconductor device according to clause 12, further including: a metal electrode which is arranged above the upper surface of the semiconductor substrate, in which the metal electrode has, a first part which overlaps the non-stacked runner, and a second part which extends to an inside further than the non-stacked runner, and the metal electrode is an electrode of a source potential.

[Clause 14] The semiconductor device according to any one of clauses 1 to 4, in which the temperature sense diode has, a main diode which has an anode connected to the anode pad, and a protection diode which has an anode connected to the cathode pad, the anode pad and the cathode pad are arranged along a first direction, and In a second direction perpendicular to the first direction in a top view, a length of the main diode is greater than a length of the protection diode.

[Clause 15] The semiconductor device according to any one of clauses 1 to 4, in which the semiconductor substrate is a silicon carbide semiconductor substrate.

[Clause 16] The semiconductor device according to any one of clauses 1 to 4, in which the semiconductor substrate is a silicon semiconductor substrate or a gallium nitride substrate.

[Clause 17] The semiconductor device according to clause 6, further including: a dielectric film provided between the upper surface of the semiconductor substrate and the metal electrode, in which in the dielectric film, a contact hole is formed, and the second part is connected to the upper surface of the semiconductor substrate via the contact hole.

[Clause 18] The semiconductor device according to clause 17, in which the contact hole surrounds the anode pad and the cathode pad.

[Clause 19] The semiconductor device according to clause 18, in which the semiconductor substrate has, a drift region of a first conductivity type, and a well region of a second conductivity type which is provided between the drift region and the upper surface of the semiconductor substrate, and the second part is connected to the well region via the contact hole.

[Clause 20] The semiconductor device according to clause 19, in which the gate runner is not provided in a range surrounded by the contact hole.

[Clause 21] The semiconductor device according to clause 19, in which the contact hole is surrounded by the gate runner.

[Clause 22] The semiconductor device according to clause 19, in which the temperature sense diode is arranged in a region between the anode pad and the cathode pad, and a distance between the anode pad and the cathode pad is 250 μm or less.

[Clause 23] The semiconductor device according to clause 19, in which the dielectric film has, a field oxide film which is provided on the upper surface of the semiconductor substrate, and an interlayer dielectric film which is provided above the field oxide film and the gate runner.

[Clause 24] A semiconductor circuit including: a plurality of semiconductor devices, each of which is the semiconductor device according to clause 18, in which the plurality of semiconductor devices are connected in parallel, and among the plurality of semiconductor devices, at least one has the temperature sense diode and at least one does not have the temperature sense diode.

What is claimed is:

1. A semiconductor device comprising:
a semiconductor substrate which has an upper surface;
a temperature sense diode which is arranged above the upper surface of the semiconductor substrate;
an anode pad which is arranged above the upper surface of the semiconductor substrate, and which is connected to an anode of the temperature sense diode;
a cathode pad which is arranged above the upper surface of the semiconductor substrate, and which is connected to a cathode of the temperature sense diode;
a gate pad which is arranged above the upper surface of the semiconductor substrate; and
a gate runner which is arranged above the upper surface of the semiconductor substrate, and which is connected to the gate pad, wherein
an entire region between the anode pad and the cathode pad does not overlap with the gate runner.

2. The semiconductor device according to claim 1, wherein the anode pad and the cathode pad do not overlap with the gate runner.

3. The semiconductor device according to claim 1, wherein the gate runner is polysilicon.

4. The semiconductor device according to claim 1, wherein the gate runner surrounds the temperature sense diode, the anode pad, and the cathode pad.

5. The semiconductor device according to claim 4, further comprising: a metal electrode which is arranged above the upper surface of the semiconductor substrate, wherein the metal electrode surrounds the anode pad and the cathode pad, and the metal electrode has, a first part which overlaps with the gate runner, and
a second part which extends to an inside further than the gate runner.

6. The semiconductor device according to claim 5, wherein the metal electrode is an electrode of a source potential.

7. The semiconductor device according to claim 5, wherein the metal electrode is at a same potential as that of the cathode pad.

8. The semiconductor device according to claim 1, wherein the semiconductor substrate has an active portion that is a region in which a semiconductor element is formed, the anode pad and the cathode pad are arranged along a first direction, in a second direction perpendicular to the first direction in a top view, the anode pad and the cathode pad face the active portion, and
the gate runner is provided between the anode pad and the cathode pad, and the active portion.

9. The semiconductor device according to claim 8, further comprising:
a field oxide film which is provided on the upper surface of the semiconductor substrate, wherein
the temperature sense diode, the anode pad, and the cathode pad are provided above the field oxide film, and
an end portion of the field oxide film is positioned below the gate runner provided between the anode pad and the cathode pad, and the active portion, in the second direction.

10. The semiconductor device according to claim 1, wherein
the semiconductor substrate has an active portion that is a region in which a semiconductor element is formed,
the gate runner has,
an outer peripheral runner portion which surrounds the active portion, and
a temperature sense runner portion which surrounds the anode pad and the cathode pad,
the outer peripheral runner portion includes a stacked runner in which a metal runner and a poly runner are stacked, and
at least a part of the temperature sense runner portion is a non-stacked runner which includes the poly runner and does not include the metal runner.

11. The semiconductor device according to claim 1, wherein the temperature sense diode has,
a main diode which has an anode connected to the anode pad, and a protection diode which has an anode connected to the cathode pad,
the anode pad and the cathode pad are arranged along a first direction, and
in a second direction perpendicular to the first direction in a top view, a length of the main diode is greater than a length of the protection diode.

12. The semiconductor device according to claim 1, wherein the semiconductor substrate is a silicon carbide semiconductor substrate.

13. The semiconductor device according to claim 1, wherein the semiconductor substrate is a silicon semiconductor substrate or a gallium nitride substrate.

14. The semiconductor device according to claim 5, further comprising: a dielectric film provided between the upper surface of the semiconductor substrate and the metal electrode, wherein in the dielectric film, a contact hole is formed, and the second part is connected to the upper surface of the semiconductor substrate via the contact hole.

15. The semiconductor device according to claim 14, wherein the contact hole surrounds the anode pad and the cathode pad.

16. The semiconductor device according to claim 15, wherein the semiconductor substrate has,
a drift region of a first conductivity type, and
a well region of a second conductivity type which is provided between the drift region and the upper surface of the semiconductor substrate, and
the second part is connected to the well region via the contact hole.

17. The semiconductor device according to claim 16, wherein the gate runner is not provided in a range surrounded by the contact hole.

18. The semiconductor device according to claim 16, wherein the contact hole is surrounded by the gate runner.

19. The semiconductor device according to claim 16, wherein the temperature sense diode is arranged in a region between the anode pad and the cathode pad, and a distance between the anode pad and the cathode pad is 250 μm or less.

20. A semiconductor circuit comprising: a plurality of semiconductor devices, each of which is the semiconductor device according to claim 15, wherein the plurality of semiconductor devices are connected in parallel, and among the plurality of semiconductor devices, at least one has the temperature sense diode and at least
one does not have the temperature sense diode.
